(19) United States
(12) Patent Application Publication
(10) Pub. No.: US 2005/0184771 A1
(43) Pub. Date: Aug. 25, 2005

(54) Semiconductor apparatus

(76) Inventors: Kiyotaka Uchigane, Yokohama-shi (JP); Tomohito Kawano, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/017,750

(22) Filed: Dec. 22, 2004

(30) Foreign Application Priority Data
Dec. 26, 2003 (JP) 2003-432788

(51) Int. Cl. H03L 7/00

(52) U.S. Cl. 327/143

(57) ABSTRACT

A semiconductor device is disclosed, which comprises a voltage dividing resistor circuit including a plurality of resistor elements connected in series between a power supply node and a ground node, a voltage detecting PMOS transistor having a gate connected to an output node of the voltage dividing resistor circuit and a source connected to the power supply node, a resistor element connected between a drain of the voltage detecting PMOS transistor and a ground node, a CMOS inverter circuit supplied with a power supply voltage through the power supply node, having an input terminal connected to a drain of the voltage detecting PMOS transistor and an output terminal for outputting a power-on detection signal, and a monitoring pad which monitors a potential of the output node of the voltage dividing resistor circuit from exterior of a semiconductor chip.

### CROSS-REFERENCE TO RELATED APPLICATIONS

This application is based upon and claims the benefit of priority from prior Japanese Patent Application No. 2003-432788, filed Dec. 26, 2003, the entire contents of which are incorporated herein by reference.

### BACKGROUND OF THE INVENTION

1. Field of the Invention

The present invention relates to a semiconductor apparatus, and particularly, relates to a power-on detection circuit for detecting input of a power source voltage, and for example, the present invention is used for a die sort test upon manufacturing a semiconductor storage apparatus.

2. Description of the Related Art

FIG. 6 illustrates an example of a power-on detection circuit that is mounted on a conventional semiconductor apparatus.

The power-on detection circuit comprises a voltage dividing resistor circuit 60, a voltage detecting PMOS transistor T1, a resistor element R3, and a CMOS inverter circuit IV, and a power-on detection is outputted from an output terminal of the CMOS inverter circuit IV. The voltage dividing resistor circuit 60 includes two resistor elements R1 and R2 connected in series between a VDD node to which a power supply voltage VDD is applied and a GND node to which ground potential is applied. The voltage detecting PMOS transistor T1 has a gate connected to an output node G of the voltage dividing resistor circuit 60 and a source connected to the VDD node. The resistor element R3 is connected between a drain of the voltage detecting PMOS transistor T1 and the ground node.

The CMOS inverter circuit IV is supplied with the power supply voltage through the VDD node, and an input terminal of the CMOS inverter circuit IV is connected to a drain of the voltage detecting PMOS transistor T1.

FIG. 7 illustrates a characteristic curve (a power-on detection characteristics characteristic curve) between a VDD and a voltage level of a power-on detection signal PONRST of a semiconductor apparatus, upon power-on, on which the power-on detection circuit shown in FIG. 6 is mounted.

When the semiconductor chip is powered on, as shown in a power-on detection characteristic in FIG. 7, a potential Vg of an output node G of a voltage dividing resistor circuit 60 is gradually increased. The potential Vg is represented by Vg=VDD−{R2/(R1+R2)×VDD}. When the VDD is low, the voltage detecting PMOS transistor T1 is turned off, because (VDD−Vg) is lower than a threshold value Vthp of the voltage detecting PMOS transistor T1. During this time, a PMOS transistor and an NMOS transistor (not shown) of the CMOS inverter circuit IV, in which the input terminal is connected to the drain of the voltage detecting PMOS transistor T1, are complementarily turned on/off, and a voltage level of the power-on detection signal PONRST rises in accordance with the VDD level.

When the VDD is increased to some extent and (VDD−Vg) becomes higher than Vthp, the voltage detecting PMOS transistor T1 is turned on. Thereby, the PMOS transistor and NMOS transistor (not shown) of the CMOS inverter circuit IV are complementarily turned off/on, and the power-on detection signal PONRST becomes GND potential.

Resistance elements R1 and R2 of the voltage dividing resistor circuit 60 are composed of, for example, impurity-diffusion resistance regions formed on a silicon substrate surface area, and because of variation of a manufacturing process, a path 61 of a current leak IL may be generated between the output node G and the GND node, as shown in FIG. 6. In this case, the potential Vg of the output node G of the voltage dividing resistor circuit 60 is lowered to a specified value or below at a timing earlier than a predetermined timing. Thus, as shown by a bold line in FIG. 7, the voltage detecting PMOS transistor T1 is turned on at a timing earlier than the predetermined timing, and a power-on detection signal PONRST rises up to the GND at a timing earlier than the predetermined timing. In other words, power-on is detected at a timing earlier than a predetermined timing.

However, in this way, if detection of power-on is carried out when VDD is lower than a predetermined value (a specified value), namely, when detection of power-on is carried out before an internal circuit of the semiconductor apparatus is set in a-normal operation, the internal circuit malfunctions, if the rising of the VDD upon power-on is gentle. Such semiconductor apparatuses are defective apparatuses, and it is necessary to exclude these apparatuses from shipment. On the contrary, even if detection of power-on is carried out before the interior circuit of the semiconductor apparatus is normally operated, in a case where the rising of the VDD upon power-on is steep, the internal circuit immediately returns to the normal operation. The slope of rising of the VDD upon power-on changes due to the operation conditions of the semiconductor apparatuses.

Thus, in the semiconductor apparatus incorporating a power-on detection circuit in which a current leak path is generated, depending on a gentle slope or a steep slope of rising of the VDD upon power-on due to operation conditions of the semiconductor apparatus, the internal circuit may normally operate or fail to normally operate. It is difficult to determine such defect of the power-on detection circuit in a die sort test in a manufacture process of the semiconductor apparatuses.

Further, in a conventional power-on clear test circuit (Jpn. Pat. Appln. KOKAI Publication No. 10-38982) and a power-on clear circuit (Jpn. Pat. Appln. KOKAI Publication No. 8-185331), there is no disclosure of a structure that a voltage level generated in a power voltage dividing resistor is monitored from outside.

As described above, according to the conventional power-on detection circuit, when a path of a current leak is generated in the voltage dividing resistor circuit and power-on is detected at a timing earlier than a predetermined timing, the interior circuit may normally operate or fail to normally operate depending on the slope of rising of the power source voltage upon power-on of the semiconductor apparatus incorporating the power-on detection circuit, and this involves a problem that it is difficult to determine the operation failure of the power-on detection circuit upon a die sort test.

### BRIEF SUMMARY OF THE INVENTION

According to an aspect of the present invention, there is provided a semiconductor device comprising:
a voltage dividing resistor circuit including a plurality of resistor elements connected in series between a power supply node and a ground node;
a voltage detecting PMOS transistor having a gate connected to an output node of the voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal; and
a monitoring pad which monitors a potential of the output node of the voltage dividing resistor circuit from exterior of a semiconductor chip.

According to another aspect of the present invention, there is provided a semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal;
a reference voltage input circuit;
a voltage comparing circuit which compares a reference voltage inputted from the reference voltage input circuit and a potential of the output node of the first voltage dividing resistor circuit; and
a monitoring pad which monitors a potential of the output node of the voltage comparing circuit from exterior of a semiconductor chip.

According to a further aspect of the present invention, there is provided a semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal; and
a second voltage dividing resistor circuit having substantially the same structure as the first voltage dividing resistor circuit, the first voltage dividing resistor circuit being replaced with the second voltage dividing resistor circuit when the first voltage dividing resistor circuit is defective.

According to a further aspect of the present invention, there is provided a semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal;
a second voltage dividing resistor circuit which generates a reference voltage, the second voltage dividing resistor circuit having substantially the same structure as the first voltage dividing resistor circuit;
a voltage comparing circuit which compares the reference voltage generated at an output node of the second voltage dividing resistor circuit and a potential of the output node of the first voltage dividing resistor circuit; and
a control circuit which carries out a control such that the first voltage dividing resistor circuit is replaced with the second voltage dividing resistor circuit when the first voltage dividing resistor circuit is defective, according to a potential of an comparison output of the voltage comparing circuit.

### BRIEF DESCRIPTION OF THE SEVERAL VIEWS OF THE DRAWING

FIG. 1 is a circuit diagram showing a power-on detection circuit and a power-on monitor circuit, which are mounted on a semiconductor apparatus according to a first embodiment of the present invention;

FIG. 2 is a circuit diagram showing a power-on detection circuit and a power-on monitor circuit, which are mounted on a semiconductor apparatus according to a second embodiment of the present invention;

FIG. 3 is a circuit diagram showing a power-on detection circuit and a power-on monitor circuit, which are mounted on a semiconductor apparatus according to a third embodiment of the present invention;

FIG. 4 is a circuit diagram showing a power-on detection circuit, a power-on monitor circuit and a power-on resistor replacing circuit, which are mounted on a semiconductor apparatus according to a fourth embodiment of the present invention;

FIG. 5 is a circuit diagram showing a power-on detection circuit, a power-on monitor circuit and a power-on resistor replacing circuit, which are mounted on a semiconductor apparatus according to a fifth embodiment of the present invention;

FIG. 6 is a circuit diagram showing an example of a power-on detection circuit, which is mounted on a conventional semiconductor apparatus; and

FIG. 7 is a characteristic diagram between a VDD and a voltage level of a power-on detection signal PONRST of a semiconductor apparatus having the power-on detection circuit shown in FIG. 6 mounted thereon upon power-on.

### DETAILED DESCRIPTION OF THE INVENTION

### First Embodiment

FIG. 1 illustrates a power-on detection circuit 11 and a power-on monitor circuit 12, which are mounted on a semiconductor apparatus according to a first embodiment of the present invention.

The power-on detection circuit 11 comprises a voltage dividing resistor circuit 10, a voltage detecting PMOS transistor T1, a resistor element R3, and a CMOS inverter circuit IV, and a power-on detection is outputted from an output terminal of the CMOS inverter circuit IV. The voltage dividing resistor circuit 10 includes two resistor elements R1 and R2 connected in series between a VDD node to which a power supply voltage VDD is applied and a GND node to which ground potential is applied. The voltage detecting PMOS transistor T1 has a gate connected to an output node G of the voltage dividing resistor circuit 10 and a source connected to the VDD node. The resistor element R3 is connected between a drain of the voltage detecting PMOS transistor T1 and the ground node. The CMOS inverter circuit IV is supplied with the power supply voltage through the VDD node, and an input terminal of the CMOS inverter circuit IV is connected to a drain of the voltage detecting PMOS transistor T1.

A power-on monitoring circuit 12 comprises a monitoring pad (P1) 13. The monitoring pad (P1) 13 is provided on a semiconductor chip and monitors a potential Vg1 (i.e., a monitored potential) of the output node G of the voltage dividing resistor circuit 10 of the power-on detection circuit 11 from exterior of the semiconductor chip. It is preferable to provide a monitor potential connecting circuit for connecting the potential Vg1 of the output node G of the voltage dividing resistor circuit 10 to the monitoring pad (P1) 13 at a monitor operation. In the present embodiment, as an example of the monitor potential connecting circuit, a resistor element 14, e.g. a CMOS transfer gate, which is turned on in the monitor operation, is inserted in a wiring connecting the output node G of the voltage dividing resistor circuit 10 to the monitoring pad (P1) 13. The CMOS transfer gate 14 is turned on in the monitor operation by a test mode control signal TEST to connect the potential Vg1 of the output node G of the voltage dividing resistor circuit 10 to the monitoring pad (P1). The test mode control signal TEST is inputted from exterior of the semiconductor chip via a test pad (not shown) provided on the semiconductor chip, for example.

In the circuit structure as above-described, when the semiconductor chip is powered on, as shown in a power-on detection characteristic in FIG. 7, the potential Vg1 of the output node G of the voltage dividing resistor circuit 10 of the power-on detection circuit 11 is gradually increased. The potential Vg1 is represented by Vg1=VDD−{R2/(R1+R2)×VDD}. When the VDD is low, the voltage detecting PMOS transistor T1 is turned off, because (VDD−Vg1) is lower than a threshold value Vthp of the voltage detecting PMOS transistor T1.

During this time, a PMOS transistor and an NMOS transistor (not shown) of the CMOS inverter circuit IV, in which the input terminal is connected to the drain of the voltage detecting PMOS transistor T1, are complementarily turned on/off, and a voltage level of the power-on detection signal PONRST rises in accordance with the VDD level.

When the VDD is increased to some extent and (VDD−Vg1) is higher than Vthp, the voltage detecting PMOS transistor T1 is turned on. Thereby, the PMOS transistor and NMOS transistor (not shown) of the CMOS inverter circuit IV are complementarily turned off/on, and the power-on detection signal PONRST becomes GND potential.

The power-on monitor circuit 12 is used to monitor the operation of the above-described power-on detection circuit 11 at a die sort test. In other words, if the CMOS transfer gate 14 is controlled to be turned on depending on a logic level of the test mode control signal TEST supplied to a test pad at the die sort test, it is possible to monitor the potential Vg1 at the time of power-on operation from outside of the semiconductor chip via the monitor pad 13. In the case that a path, through which the current of the voltage dividing resistor circuit 10 is leaked, is generated and power-on is detected at a timing earlier than a predetermined timing, a rising speed of the potential Vg1 of the output node G is lower than a specified value, and accordingly, by monitoring the potential Vg1, it is possible to easily determine the operation failure of the power-on detection circuit 11.

### Second Embodiment

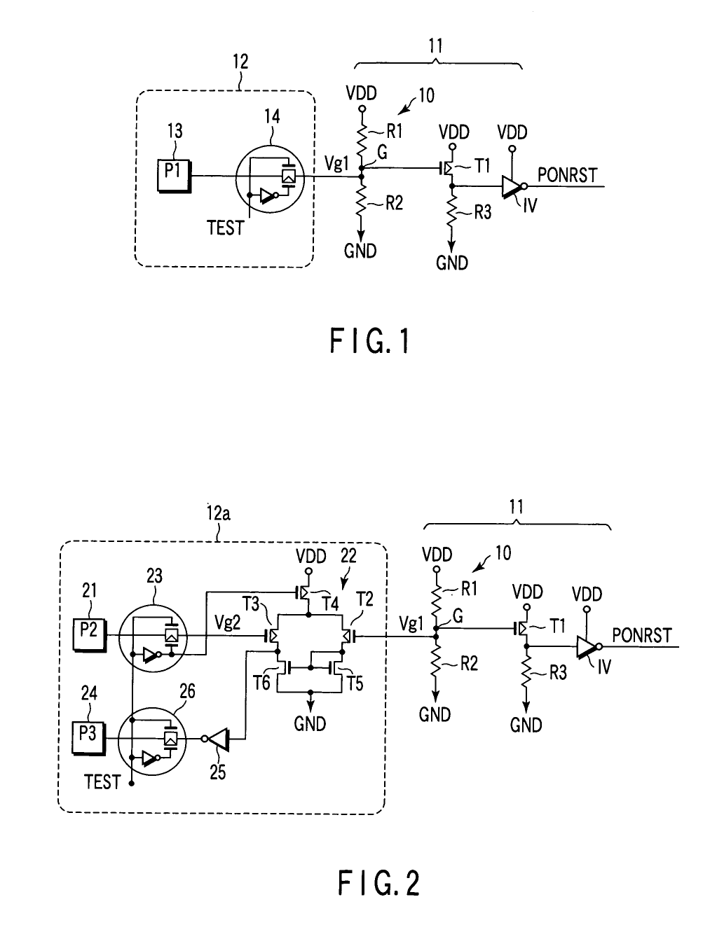

In the power-on monitor circuit 12 according to the first embodiment, the potential Vg1 is monitored from outside of the semiconductor chip. In the power-on monitor circuit 12a according to a second embodiment of the present invention, change is made to the first embodiment, and a result of comparison between the potential Vg1 and an external input potential is monitored from outside of the semiconductor chip. The second embodiment will be described below with reference to FIG. 2.

FIG. 2 illustrates the power-on detection circuit 11 and a power-on monitor circuit 12a, which are mounted on a semiconductor apparatus according to the second embodiment of the present invention. The same reference numerals are given to the same parts as those in FIG. 1.

The power-on detection circuit 11 in FIG. 2 is the same as the power-on detection circuit 11 as described with reference to FIG. 1. In comparison with the power-on monitor circuit 12 described above with reference to FIG. 1, the power-on monitor circuit 12a is provided with a reference voltage input pad (P2) 21 for inputting a reference voltage Vg2 from outside of the semiconductor chip. In addition, a voltage comparing circuit 22 is provided in the power-on monitor circuit 12a. The voltage comparing circuit 22 compares the reference voltage Vg2 inputted to the reference voltage input pad 21 with the potential Vg1 of the output node G of the voltage dividing resistor circuit 10 of the power-on detection circuit 11. On the other hand, the CMOS transfer gate 14 for monitor potential connection is removed. The reference voltage Vg2 is set at a value slightly lower than the specified value of the monitor potential Vg1.

The voltage comparing circuit 22 is formed of a differential amplifier circuit. The differential amplifier circuit comprises a pair of PMOS transistors T2 and T3 forming a differential pair for comparison, a PMOS transistor T4 for current comparison, and NMOS transistors T5 and T6 for a current mirror load.

It is preferable to provide a reference voltage connecting circuit for connecting the reference voltage Vg2 inputted to the reference voltage input pad 21 with one of the pair of input nodes of the voltage comparing circuit 22 at the monitor operation. In the present embodiment, as an example of the reference voltage connecting circuit, a switch element 23, e.g. a CMOS transfer gate, is provided. The switch element 23 is turned on at the monitor operation. The switch element 23 is inserted in a wiring connecting the reference voltage input pad 21 to said one of the pair of input nodes of the voltage comparing circuit 22. The switch element 23, e.g. a CMOS transfer gate, is turned on at the monitor operation by a test mode control signal TEST to connect the reference voltage Vg2 inputted to the reference voltage input pad 21 to said one of the pair of input nodes of the voltage comparing circuit 22. The test mode control signal TEST is inputted from exterior of the semiconductor chip via a test pad (not shown) provided on the semiconductor chip, for example.

Also, in the present embodiment, as an example of a comparison result transfer circuit for connecting a comparison output of the voltage comparing circuit 22 to a monitor pad (P3) 24 at the monitor operation, a structure of an inverter circuit 25 and a switch element 26, e.g. a CMOS transfer gate, is provided. The switch element 26 is turned on at the monitor operation. The switch element 26 is inserted in a wiring connecting an output node of the voltage comparing circuit 22 and the monitor pad 24. The switch element 26, e.g. a CMOS transfer gate, is turned on at the monitor operation by a test mode control signal TEST to connect the comparison output of the voltage comparing circuit 22 to the monitor pad 24.

With the above-described circuit structure, the power-on detection circuit 11 is operated in the same manner as the power-on detection circuit 11 of the first embodiment. In the power-on monitor circuit 12a, at the die sort test, CMOS transfer gates 23 and 26 are controlled to be turned on by the test mode control signal TEST, the voltage comparing circuit 22 compares the reference voltage Vg2 inputted to the reference voltage input pad 21 and the potential Vg1 of the output node G of the voltage dividing resistor circuit 10 of the power-on detection circuit 11 upon power-on, and the comparison result is taken out at the monitor pad 24. Thus, it is possible to monitor the comparison result of the voltage comparing circuit 22 from outside of the semiconductor chip. In the case that a path, through which the current of the dividing resistive circuit 10 is leaked, is generated and power-on is detected at a timing earlier than a predetermined timing, the potential Vg1 of the output node G does not rise to a specified value (a reference voltage) within a comparison timing after a predetermined time has passed from power-on. Thus, a logic level of the potential of the comparison output node of the voltage comparing circuit 22 is inverted. Accordingly, by monitoring the voltage comparison result at the comparison timing from outside of the semiconductor chip via the monitor pad 24, it is possible to easily determine the operation failure of the power-on detection circuit 11.

### Third Embodiment

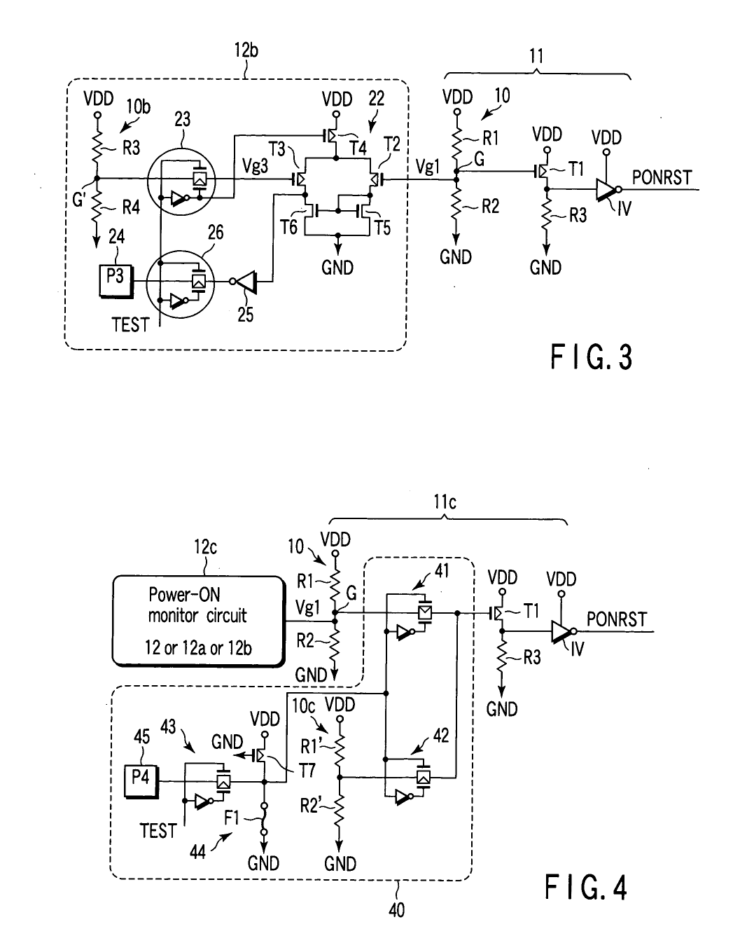

In the power-on monitor circuit 12a according to the second embodiment, the reference voltage Vg2 for comparison is inputted to the reference voltage input pad 21 from outside of the semiconductor chip. According to a third embodiment of the present invention, change is made to the second embodiment, and a reference voltage Vg3 for comparison is generated in the semiconductor chip. The third embodiment will be described below with reference to FIG. 3.

FIG. 3 illustrates the power-on detection circuit 11 and a power-on monitor circuit 12b, which are mounted on a semiconductor apparatus according to the third embodiment of the present invention.

The power-on detection circuit 11 in FIG. 3 is the same as the power-on detection circuit 11 as described with reference to FIG. 1. The power-on monitor circuit 12b is different from the power-on monitor circuit 12a described with reference to FIG. 2 in that the reference voltage input pad 21 is removed, a voltage dividing resistor circuit 10b for generating a reference voltage, which is substantially the same as the voltage dividing resistor circuit 10 of the power-on detection circuit 11, is provided, and a potential Vg3 of the output node of the voltage dividing resistor circuit 10b is transferred to one comparison input node of the voltage comparing circuit 22 via the CMPS transfer gate 23 for transfer of a reference voltage. Other elements are the same as those in FIG. 2, and the same reference numerals are given to these elements. The potential Vg3 of the output node of the voltage dividing resistor circuit 10b for generating a reference voltage is set to a value slightly lower than a specified value of the voltage Vg1 of the output node G of the voltage dividing resistor circuit 10 of the power-on detection circuit 11.

The operation of the configuration as described with reference to FIG. 3 is different from the operation of the configuration as described with reference to FIG. 2 in that the potential Vg3 of the output node of the voltage dividing resistor circuit 10b for generating a reference voltage is used in place of the reference voltage input Vg2. However, these operations are basically the same. Accordingly, it is possible to easily determine the operation failure of the power-on detection circuit 11, by monitoring the voltage comparison result taken at a comparison timing after a predetermined time has passed from power-on.

### Fourth Embodiment

According to the first embodiment, the power-on monitor circuit 12 merely monitors the potential of the output node G of the voltage dividing resistor circuit 10 of the power-on detection circuit 11 upon operation of the monitor, and according to the second and third embodiments, the power-on monitor circuits 12a and 12b merely monitor the comparison result of the voltage comparing circuit 22 upon operation of the monitor. However, according to the fourth embodiment, change is made such that a dividing resistor circuit for replacement is provided, and if the operation failure of the power-on detection circuit 11 is determined by monitor operation, the voltage dividing resistor circuit 10 of the power-on detection circuit 11 is replaced with the dividing resistor circuit for replacement. The fourth embodiment will be described below with reference to FIG. 4. The same reference numerals are given to the same parts as those in FIG. 1.

FIG. 4 illustrates a power-on detection circuit 11c, a power-on monitor circuit 12c, and a power-on resistor replacing circuit 40, which are mounted on a semiconductor apparatus according to the fourth embodiment of the present invention.

In the fourth embodiment shown in FIG. 4, the power-on resistor replacing circuit 40 comprises a first switch circuit 41, a voltage dividing resistor circuit 10c for generating a reference voltage, a second switch circuit 42, and a fuse circuit 44. The first switch circuit 41 is inserted between the output node G of the voltage dividing resistor circuit 10 of the power-on detection circuit 11c and the gate of the transistor T1 for detection of a voltage. The voltage dividing resistor circuit 10c comprises resistor elements R1′ and R2′ and has substantially the same structure as the voltage dividing resistor circuit 10 of the power-on detection circuit 11c. The second switch circuit 42 is inserted between an output node of the voltage dividing resistor circuit 10c and the gate of the voltage detection transistor T1 of the power-on detection circuit 11c. The fuse circuit 44 generates a switch signal for complementarily switching the first switch circuit 41 and the second switch circuit 42.

The fuse circuit 44 is formed of a PMOS transistor T7 having a gate connected to GND and a fuse element (e.g., a metal fuse) F1, which are connected in series between a VDD node and GND. The fuse circuit 44 also comprises a third switch circuit 43 connected between PMOS transistor T7 and the fuse element F1. The third switch circuit 43 is turned on at the monitor operation.

In FIG. 4, the power-on monitor circuit 12c may be any of the above-described power-on monitor circuits 12, 12a, and 12b as described respectively with reference to FIGS. 1, 2 and 3.

The operation of the power-on detection circuit 11c and the power-on monitor circuit 12c of the configuration as above-described with reference to FIG. 4 is basically the same as that of the power-on detection circuits 11 and the monitor circuit 12 of the configuration as described with reference to FIG. 1, that of the power-on detection circuit 11a and the monitor circuit 12a of the configuration as described with reference to FIG. 2, and that of the power-on detection circuit 11b and the power-on monitor circuit 12b of the configuration as described with reference to FIG. 3. In the power-on resistor replacing circuit 40, a fuse element F1 is normally electrically conducted, and a potential of a connection node between a PMOS transistor T7 and the fuse element F1 is GND. Accordingly, a first switch circuit 41 and a second switch circuit 42 are correspondingly turned on and off by a switching signal from a fuse circuit 44. As a result of the monitor operation, when the power-on monitor circuit 12c determines an operation failure of the power-on detection circuit 11c, a predetermined voltage is applied to an exterior input pad 45 and the fuse element F1 is blown out to be electrically non-conducted. Thereby, a potential of a connection node between the PMOS transistor T7 and the fuse element F1 is connected to VDD, and the first switch circuit 41 and the second switch circuit 42 are correspondingly changed to be off and on by the switching signal from the fuse circuit 44. Accordingly, in the power-on detection circuit 11c, an output potential of a dividing resistor circuit 10c for replacement, in place of the output potential of the dividing resistor circuit 10, is inputted to the gate of the voltage detection transistor T1. Thus, the operation failure of the power-on detection circuit 11c is prevented if the voltage dividing resistor circuit 10c is normal.

### Fifth Embodiment

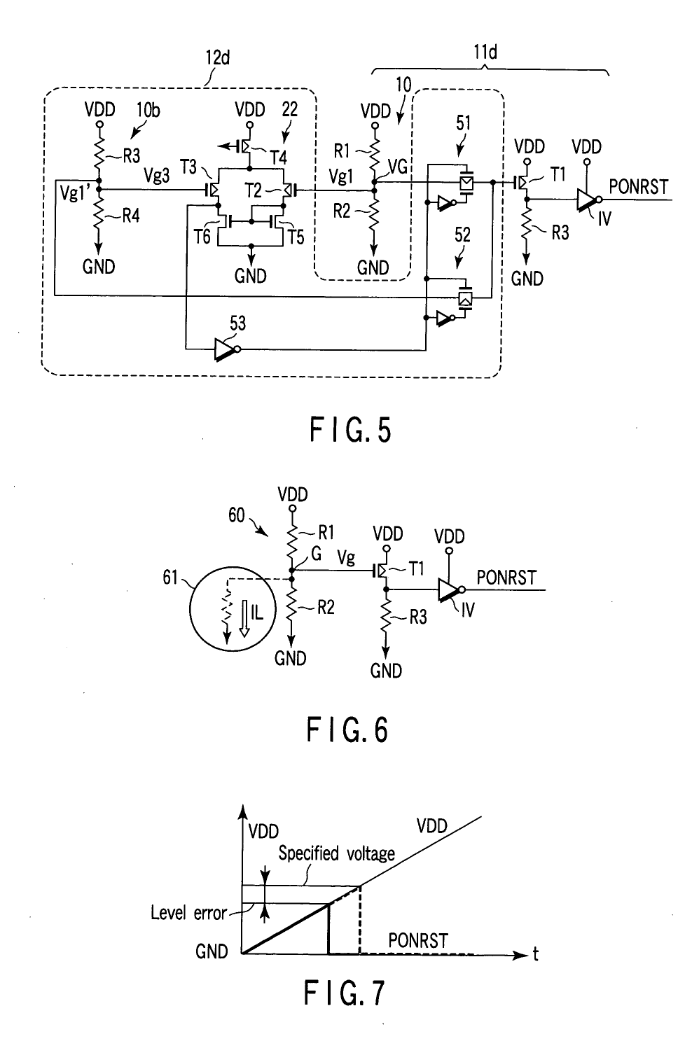

According to the third embodiment described with reference to FIG. 3, the power-on monitor circuit 12b merely monitors a comparison result of the voltage comparing circuit 22 upon operation of the monitor. However, according to a fifth embodiment, change is made to the third embodiment such that the voltage dividing resistor circuit 10 of the power-on detection circuit 11 is replaced with a voltage dividing resistor circuit 10b for generating a reference voltage. The fifth embodiment will be described below with reference to FIG. 5.

FIG. 5 illustrates a power-on detection circuit 11d and a power-on monitor circuit 12d, which are mounted on a semiconductor apparatus according to the fifth embodiment of the present invention. The same reference numerals are given to the same parts as those in FIG. 3.

In the fifth embodiment shown in FIG. 5, the power-on monitor circuit 12d includes the voltage comparing circuit 22 and the dividing resistor circuit 10b in the power-on monitor circuit 12b as described in the third embodiment with reference to FIG. 3. The power-on monitor circuit 12d also includes a first switch circuit 51 inserted between the output node G of the dividing resistive circuit 10 of the power-on detection circuit 11d and the gate of the transistor T1 for detection of a voltage, a second switch circuit 52 inserted between a output node G′ of the voltage dividing resistor circuit 10b of the voltage comparing circuit 22 and the gate of the voltage detection transistor T1 of the power-on detection circuit lid, and an inverter circuit 53 for generating a switching signal for complementarily controlling the first switch circuit 51 and the second switch circuit 52 on the basis of a comparison output of the voltage comparing circuit 22.

The operation of the power-on detection circuit 11d and the power-on monitor circuit 12d according to the present embodiment is basically the same as that of the power-on detection circuit 11 and the power-on monitor circuit 12b described in the third embodiment with reference to FIG. 3. The first switch circuit 51 and the second switch circuit 52 are turned to be on and off or to be off and on by a switch signal on the basis of the comparison output of the voltage comparing circuit 22 upon power-on. Under such a condition, if the operation of the power-on detection circuit 11d is normal, a logic level of the comparison output of the voltage comparing circuit 22 is not inverted. Thus, the states of the first switch circuit 51 and the second switch circuit 52 are retained as they stand.

On the contrary, when the operation of the power-on detection circuit lid upon power-on is failed, the logic level of the comparison output of the voltage comparing circuit 22 is inverted, and the first switch circuit 51 and the second switch circuit 52 are turned to be off and on or to be on and off by the switch signal. Accordingly, in place of the output potential Vg1 of the voltage dividing resistor circuit 10, the output potential Vg3, i.e. Vg1′, of the voltage dividing resistor circuit 10b for generating a reference voltage is inputted to the gate of the transistor T1 for detection of a voltage. Hence, the operation failure of the power-on detection circuit 11d is prevented.

According to the semiconductor apparatus of the present invention, it is possible to easily determine failure of the operation of the incorporated power-on detection circuit upon a die sort test.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a voltage dividing resistor circuit including a plurality of resistor elements connected in series between a power supply node and a ground node;
a voltage detecting PMOS transistor having a gate connected to an output node of the voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal; and
a monitoring pad which monitors a potential of the output node of the voltage dividing resistor circuit from exterior of a semiconductor chip.

2. A semiconductor device according to claim 1, further comprising a switch provided between the output node of the voltage dividing resistor circuit and the monitoring pad, and controlled to be on/off by a test signal.

3. A semiconductor device according to claim 2, wherein the switch is comprised of a CMOS transfer gate provided between the output node of the voltage dividing resistor circuit and the monitoring pad, and controlled to be on/off by the test signal.

4. A semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal;
a reference voltage input circuit;
a voltage comparing circuit which compares a reference voltage inputted from the reference voltage input circuit and a potential of the output node of the first voltage dividing resistor circuit; and
a monitoring pad which monitors a potential of the output node of the voltage comparing circuit from exterior of a semiconductor chip.

5. A semiconductor device according to claim 2, wherein the voltage comparing circuit comprises a differential amplifier circuit.

6. A semiconductor device according to claim 4, wherein the differential amplifier circuit comprises a pair of differential transistors, a gate of one of the pair of differential transistors being inputted with the reference voltage from the reference voltage input circuit, and a gate of the other of the pair of differential transistors being inputted with the potential of the output node of the first voltage dividing resistor circuit.

7. A semiconductor device according to claim 6, further comprising a switch provided between the gate of said one of the pair of differential transistors and the reference voltage input circuit, and controlled to be on/off by a test signal.

8. A semiconductor device according to claim 7, wherein the switch is comprised of a CMOS transfer gate provided between the gate of said one of the pair of differential transistors and the reference voltage input circuit, and controlled to be on/off by the test signal.

9. A semiconductor device according to claim 6, further comprising a switch provided between an output terminal of the differential amplifier circuit and the monitoring pad, and controlled to be on/off by a test signal.

10. A semiconductor device according to claim 9, wherein the switch is comprised of a CMOS transfer gate provided between the output terminal of the differential amplifier circuit and the monitoring pad, and controlled to be on/off by the test signal.

11. A semiconductor device according to claim 4, wherein the reference voltage of the reference voltage input circuit is set to be lower than the potential of the output node of the first voltage dividing resistor circuit.

12. A semiconductor device according to claim 4, wherein the reference voltage input circuit comprises a reference voltage input pad inputted with the reference voltage from exterior of the semiconductor chip, the voltage comparing circuit compares the reference voltage inputted from exterior of the semiconductor chip via the reference voltage input pad circuit and the potential of the output node of the first voltage dividing resistor circuit.

13. A semiconductor device according to claim 4, wherein the reference voltage input circuit comprises a second voltage dividing resistor circuit, the second voltage dividing resistor circuit having substantially the same structure as the first voltage dividing resistor circuit, and generating the reference voltage from an output node of the second voltage dividing resistor circuit, and the voltage comparing circuit comparing the reference voltage from the output node of the second voltage dividing resistor circuit and the potential of the output node of the first voltage dividing resistor circuit.

14. A semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal; and
a second voltage dividing resistor circuit having substantially the same structure as the first voltage dividing resistor circuit, the first voltage dividing resistor circuit being replaced with the second voltage dividing resistor circuit when the first voltage dividing resistor circuit is defective.

15. A semiconductor device comprising:
a first voltage dividing resistor circuit including a plurality of resistor elements connected in series between a power supply node and a ground node;
a voltage detecting PMOS transistor having a gate connected to an output node of the first voltage dividing resistor circuit and a source connected to the power supply node;
a resistor element connected between a drain of the voltage detecting PMOS transistor and a ground node;
a CMOS inverter circuit supplied with a power supply voltage through the power supply node, having an input terminal connected to a drain of the voltage detecting PMOS transistor and an output terminal for outputting a power-on detection signal;
a second voltage dividing resistor circuit which generates a reference voltage, the second voltage dividing resistor circuit having substantially the same structure as the first voltage dividing resistor circuit;
a voltage comparing circuit which compares the reference voltage generated at an output node of the second voltage dividing resistor circuit and a potential of the output node of the first voltage dividing resistor circuit; and
a control circuit which carries out a control such that the first voltage dividing resistor circuit is replaced with the second voltage dividing resistor circuit when the first voltage dividing resistor circuit is defective, according to a potential of an comparison output of the voltage comparing circuit.
